(19) United States
(12) Patent Application Publication
(10) Pub. No.: US 2024/0392426 A1
(43) Pub. Date: Nov. 28, 2024

(54) METHOD OF SURFACE TREATMENT

(71) Applicant: Samsung Electronics Co., Ltd., Suwon-si (KR)

(72) Inventors: Younseon WANG, Suwon-si (KR); Jeonghoon NAM, Suwon-si (KR); Youngkwon KIM, Suwon-si (KR); Hyunseo CHOI, Suwon-si (KR); Keonwoo KIM, Suwon-si (KR); Dougyong SUNG, Suwon-si (KR); Junho IM, Suwon-si (KR)

(73) Assignee: Samsung Electronics Co., Ltd., Suwon-si (KR)

(21) Appl. No.: 18/430,308

(22) Filed: Feb. 1, 2024

(30) Foreign Application Priority Data
May 24, 2023 (KR) 10-2023-0067049

(51) Int. Cl. C23C 8/36; C23C 8/80; C23C 16/44; H01J 37/32

(52) U.S. Cl. CPC C23C 8/36; C23C 8/80; C23C 16/4404; H01J 37/32357; H01J 37/32715; H01J 2237/332

(57) ABSTRACT

A method of surface treatment, includes: providing a component in a first process chamber; generating fluorine plasma with a remote plasma source connected to the first process chamber; and forming a protective layer on a surface of the component by providing the fluorine plasma to the first process chamber, wherein the protective layer comprises magnesium fluoride, wherein a magnesium content of the component is about 0.5 wt % to about 5.5 wt %, and wherein a thickness of the protective layer is about 100 nm to about 300 nm.

### CROSS-REFERENCE TO RELATED APPLICATION

This application is based on and claims priority under 35 U.S.C. § 119 to Korean Patent Application No. 10-2023-0067049 filed on May 24, 2023, in the Korean Intellectual Property Office, the disclosure of which is incorporated herein by reference in its entirety.

### BACKGROUND

### 1. Field

The disclosure relates to a method of surface treatment.

### 2. Description of Related Art

With an increase in a temperature of a semiconductor manufacturing process, a cleaning process temperature is also increasing for process efficiency. Fluorine radicals used in a cleaning process may cause fluorine on a surface of a component to cause component defects and particle issues in a semiconductor process, and there is a need for a technology to prevent such problems.

### SUMMARY

Provided is a method of surface treatment. The method may include forming a protective layer through a high-temperature plasma pretreatment in order to suppress fluorine on a surface of components exposed to plasma among components of a process chamber.

According to an aspect of the disclosure, a method of surface treatment, includes: providing a component in a first process chamber; generating fluorine plasma with a remote plasma source connected to the first process chamber; and forming a protective layer on a surface of the component by providing the fluorine plasma to the first process chamber, wherein the protective layer comprises magnesium fluoride, wherein a magnesium content of the component is about 0.5 wt % to about 5.5 wt %, and wherein a thickness of the protective layer is about 100 nm to about 300 nm.

According to an aspect of the disclosure, a method of surface treatment, includes: installing a component in a process chamber; generating fluorine plasma with a remote plasma source connected to the process chamber; and forming a protective layer on a surface of the component by providing the fluorine plasma to the process chamber, wherein the protective layer comprises magnesium fluoride, wherein a magnesium content of the component is about 0.5 wt % to about 5.5 wt %, and wherein a thickness of the protective layer is about 100 nm to about 300 nm.

According to an aspect of the disclosure, a method of surface treatment, includes: providing a component including a bulk layer including aluminum and magnesium in a process chamber; annealing the component to form, on the bulk layer, a surface region including a higher magnesium content than that of the bulk layer; generating fluorine plasma with a remote plasma source connected to the process chamber; and forming a protective layer on the surface region by providing the fluorine plasma to the process chamber, wherein the protective layer comprises magnesium fluoride, wherein a magnesium content of the component is about 0.5 wt % to about 5.5 wt %, and wherein a thickness of the protective layer is about 100 nm to about 300 nm.

According to embodiments of the disclosure, magnesium fluoride may be formed on a surface of a component including aluminum, thereby preventing fluorine radicals from penetrating into the component and preventing aluminum fluoride from being formed. Accordingly, a lifecycle of the component may be extended, and particles in a process chamber may be prevented and reduced.

A change in surface roughness of a component may be reduced by suppressing aluminum fluoride by a protective layer, thereby maintaining a constant condition in a process chamber. When performing thin film deposition using a deposition process during a semiconductor process, a change in the illuminance of a fluorinated shower head may lead to a temperature change of the substrate or a chamber impedance to prevent a reduction of a thin film deposition rate, thereby reducing a time-dependent change in a semiconductor manufacturing process.

Advantages and effects of the disclosure are not limited to the foregoing content and may be more easily understood in the process of describing a specific embodiment of the disclosure.

### BRIEF DESCRIPTION OF DRAWINGS

The above and other aspects, features, and advantages of the disclosure will be more clearly understood from the following detailed description, taken in conjunction with the accompanying drawings, in which:

FIG. 1 is a flowchart illustrating a method of surface treatment according to an embodiment of the disclosure;

FIG. 2 is a schematic configuration diagram of a device of surface treatment according to an embodiment of the disclosure;

FIGS. 3 to 5 are diagrams illustrating a method of surface treatment according to an embodiment of the disclosure;

FIG. 6 is a flowchart illustrating a method of surface treatment according to an embodiment of the disclosure;

FIGS. 7 and 8 are views illustrating a method of surface treatment according to an embodiment of the disclosure; and

FIG. 9 is a view illustrating an annealing method according to an embodiment of the disclosure.

### DETAILED DESCRIPTION

Hereinafter, embodiments of the disclosure will be described with reference to the accompanying drawings. The embodiments described herein are non-limiting example embodiments, and thus, the disclosure is not limited thereto and may be realized in various other forms.

Although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure.

When an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. In one embodiment, “at least one of A, B, and C” includes any of the following combinations: A, B, C, A and B, A and C, B and C, and A and B and C, and any variations thereof. Similarly, the term “set” means one or more. Accordingly, the set of items may be a single item or a collection of two or more items.

In the detailed description, components described with reference to the terms “part”, “unit”, “module”, “block”, “-er or -or”, etc. and function blocks illustrated in drawings will be implemented with software, hardware, or a combination thereof. In one embodiment, the software may be a machine code, firmware, an embedded code, and application software. In one embodiment, the hardware may include an electrical circuit, an electronic circuit, a processor, a computer, an integrated circuit, integrated circuit cores, a pressure sensor, an inertial sensor, a microelectromechanical system (MEMS), a passive element, or a combination thereof.

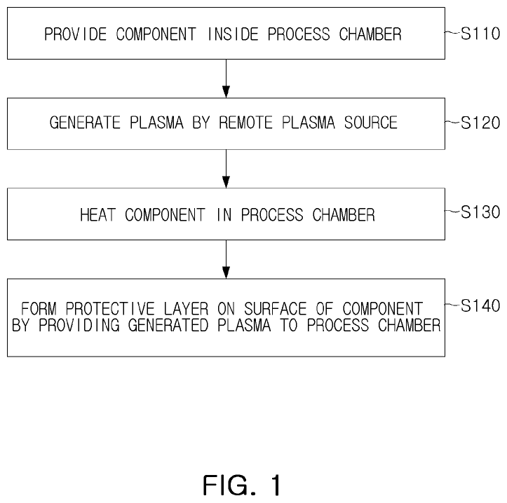

FIG. 1 is a flowchart illustrating a method of surface treatment according to an embodiment of the disclosure.

In FIG. 1, a method of surface treatment of a component according to an embodiment of the disclosure may include providing a component in a process chamber connected to a remote plasma source (operation S110), generating fluorine plasma from the remote plasma source (operation S120), heating the component (operation S130), and forming a protective layer on a surface of the component by providing the generated fluorine plasma to the process chamber (operation S140).

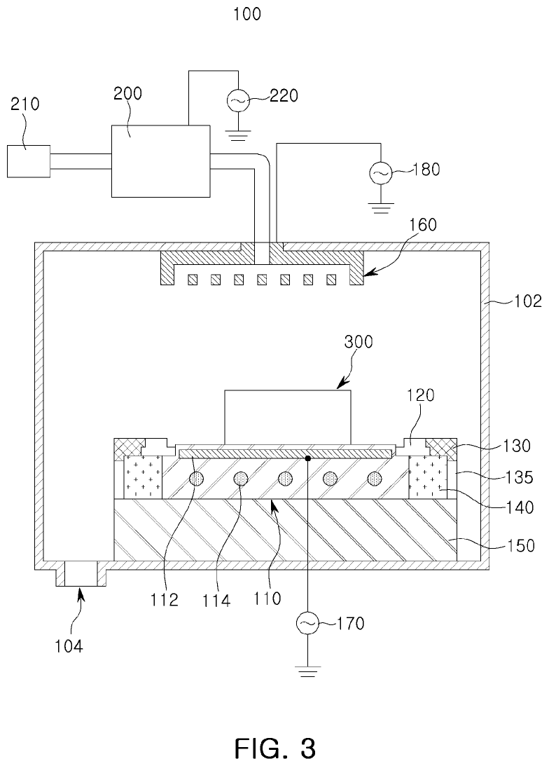

FIGS. 3 to 5 are diagrams illustrating a method of surface treatment according to an embodiment of the disclosure.

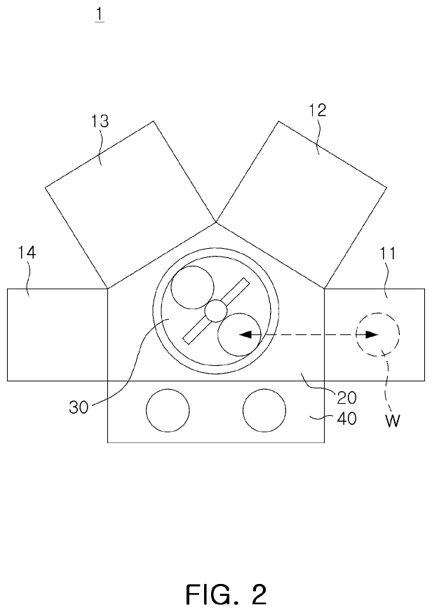

FIG. 2 is a schematic configuration diagram of a device of surface treatment according to an embodiment of the disclosure. FIG. 3 illustrates a process chamber of a processing device 1 according to an embodiment.

In FIG. 2, the processing device 1 according to an embodiment of the disclosure may include a plurality of process chambers 11 to 14. At least one of the plurality of process chambers 11 to 14 may be a process chamber for surface treatment. Furthermore, in an embodiment, at least one of the plurality of process chambers 11 to 14 may be a process chamber performing a semiconductor device manufacturing process.

A transfer chamber 20 and a load-lock chamber 40 may include a transfer robot 30, and the transfer robot 30 of the transfer chamber 20 and the load-lock chamber 40 may transfer components and substrates W, which are process objects. In one embodiment, the transfer robot 30 of the transfer chamber 20 may remove a process object such as a substrate W from the load-lock chamber 40 and transfer the process target to the plurality of process chambers 11 to 14, or transfer the process object between the plurality of process chambers 11 to 14. In an embodiment of the disclosure, the transfer robot 30 may be a handler. The transfer robot 30 may include a chuck for fixing the process object, and a plurality of protrusions in contact with the process object may be formed on an upper portion of the chuck. The transfer robot 30 may further include a linear stage for transferring the process object.

A process chamber 100 illustrated in FIG. 3 may correspond to one of the plurality of process chambers 11 to 14 illustrated in FIG. 2.

In an embodiment of the disclosure, the process chamber 100 may include a housing 102, an outlet 104, a support 110, a focus ring 120, an insulation ring 130, a support ring 135, an edge ring 140, an isolator 150, a shower head 160, a first power source 170, and a second power source 180. The housing 102 may provide a space therein in which a surface treatment process such as plasma fluoride treatment is performed. The outlet 104 may discharge by-products generated in the above-described processes.

The support 110 may support an object to be treated. In an embodiment of the disclosure, the object to be treated may be a component constituting the process chamber 100. The support 110 may be an electrostatic chuck, and may include a lower electrode 112 and a heater 114.

The support 110 may heat the object to be treated, disposed thereon. In one embodiment, the object to be treated may be heated by the heater 114 disposed in the support 110. A flow path through which a coolant flows may be formed in the support 110, and the object to be treated may be cooled by the coolant. In some embodiments of the disclosure, the heater 114 may be disposed outside of the support 110.

The focus ring 120 may be disposed to surround an edge of an upper surface of the support 110. The focus ring 120 may surround a portion of the support 110 on which the object to be treated is disposed. That is, the focus ring 120 may have a ring shape surrounding an upper portion of the support 110. The focus ring 120 may prevent damage to the support 110 in a plasma treatment process.

In one embodiment, when the focus ring 120 includes a conductive material, the focus ring 120 may have an electrode property as a conductor through which electricity flows. The focus ring 120 may function to expand an electric field region formed between the lower electrode 112 and the shower head 160 so that the object to be treated is treated uniformly as a whole. The focus ring 120 may be formed of a semiconductor material such as silicon (Si), silicon carbide (SiC), and gallium bis (GaAs).

The insulating ring 130 may have a ring shape to surround an external circumferential surface of the focus ring 120. The insulating ring 130 may include a material different from that of the focus ring 120. More specifically, the insulating ring 130 may include a material having etching resistance as compared to the focus ring 120 in an etching process using plasma. In one embodiment, the insulating ring 130 may include a quartz.

The edge ring 140 may have a ring shape surrounding a lower portion of the support 110. The edge ring 140 may be disposed below the focus ring 120 and the insulating ring 130 and may support the focus ring 120 and the insulating ring 130. The edge ring 140 may include a metallic material

The insulating ring 130 may be supported by the support ring 135. The support ring 135 may be in contact with a portion of a lower surface of the insulating ring 130. The support ring 135 may be disposed to surround an external circumferential surface of the edge ring 140. The support ring 135 may include a material that is resistant to etching in a plasma etching gas, for example, a quartz, but the disclosure is not limited thereto.

The isolator 150 may be disposed below the support 110. The isolator 150 may include an insulating material, for example, ceramic. The focus ring 120, the insulating ring 130, the support ring 135, and the edge ring 140 may form a ring structure. In some embodiments of the disclosure, the ring structure and isolator 150 may include aluminum (Al) and magnesium (Mg).

The shower head 160 may be disposed in an upper portion of the process chamber 100 and may be disposed to face the support 110. The shower head 160 may function as an RF electrode for spraying a process gas onto an object to be treated, or generating plasma. In one embodiment, the lower electrode 112 may be connected to the first power source 170, the shower head 160 may be connected to the second power source 180, and the lower electrode 112 and the shower head 160 may be used to generate plasma in the process chamber 100. The shower head 160 may be formed of a conductive material or may include a metallic electrode. In one embodiment, the shower head 160 may be made of aluminum (Al) or an alloy including aluminum (Al). In an embodiment of the disclosure, a heater may be included in the shower head 160 to heat the shower head 160.

In an embodiment of the disclosure, the process chamber 100 may be connected to a remote plasma source 200 and a gas supply unit 210. In one embodiment, the gas supply unit 210 may provide a source gas g1 to the remote plasma source 200. The remote plasma source 200 may be connected to a third power source 220 and may form plasma from the source gas g1. The plasma formed in the remote plasma source 200 may be provided to a space in the process chamber 100 through the shower head 160.

In an embodiment of the disclosure, the process chamber 100 may further include a liner. The liner may have a cylindrical shape in which an upper surface and a lower surface thereof are open. In one embodiment, an external portion of the liner may be disposed to surround the isolator 150 and the support ring 135, and the external portion of the liner may be provided along a sidewall of the process chamber 100. The liner may be used to prevent the process chamber 100 from being damaged by arc discharge. In one embodiment, the liner may include a conductive material, for example, aluminum (Al).

Hereinafter, a method of surface treatment of a component will be described referring to FIGS. 1, 3, 4, and 5. The surface treatment of the component may be performed before a component is installed or replaced in a semiconductor manufacturing process chamber.

In FIGS. 1 and 3, a component 300 may be provided in a process chamber 100 connected to the remote plasma source 200 (operation S110). In the present specification, a ‘component’ may refer to a component constituting a process chamber. In one embodiment, the component 300 may be a component constituting a deposition process chamber or an etching process chamber among a plurality of process chambers 11 to 14. Since the component 300 is provided in the process chamber 100 for surface treatment, after the surface treatment is completed, the component 300 may be installed in a process chamber identical to or different from the process chamber 100 in which the surface treatment is performed.

In an embodiment of the disclosure, the component 300 may be formed of aluminum (Al), or may be formed of aluminum alloys including aluminum (Al). In one embodiment, the component 300 may further include metals such as magnesium (Mg), silicon (Si), chromium (Cr), and copper (Cu) in addition to aluminum (Al).

In some embodiments of the disclosure, the component 300 may be a component including aluminum (Al), such as the shower head 160, an internal wall of the housing 102, an internal wall of the outlet 104, the liner, or the heater 114. In an embodiment of the disclosure, the component 300 may include aluminum (Al) and magnesium (Mg), and a content of magnesium (Mg) may be about 0.5 percentage by weight (wt %) to about 5.5 wt %. In an embodiment of the disclosure, the magnesium (Mg) content of the component 300 may be about 0.5 wt % to about 2 wt %, or about 2 wt % to about 5.5 wt %.

In an embodiment of the disclosure, the component 300 may be disposed on an upper surface of the support 110. Since the component 300 is disposed on the support 110 to heat the component 300, a position of the component 300 is not limited thereto. Furthermore, a shape of the component 300 illustrated in FIG. 2B is exemplary and the disclosure is not limited thereto. In some embodiments of the disclosure, the component 300 may be disposed in a position other than the upper surface of the support 110. In one embodiment, the component 300 may be surface-treated while being installed in the process chamber 100. When the shower head 160 is surface-treated, the surface treatment may be performed while the shower head 160 is installed to face the support 110 in the process chamber 100 as described in FIG. 2B.

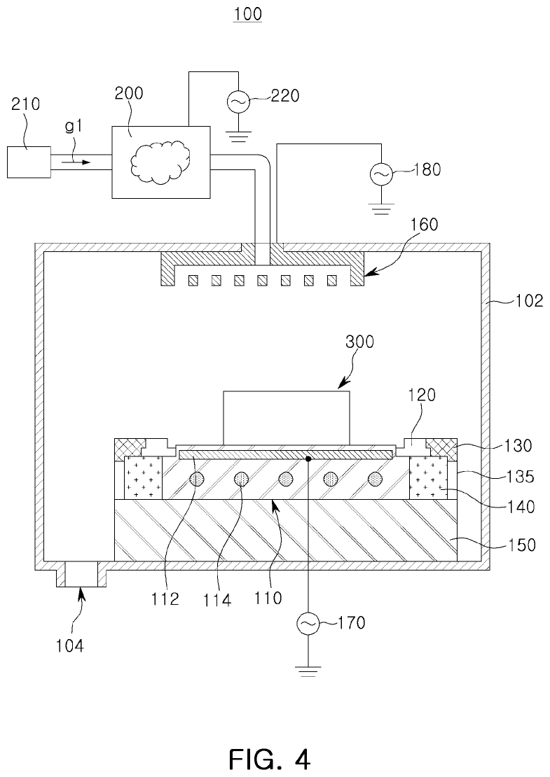

In FIGS. 1 and 4, fluorine plasma may be generated in the remote plasma source 200 (operation S120). In one embodiment, the gas supply unit 210 may provide the source gas g1 to the remote plasma source 200. The source gas g1 may be a gas containing fluorine to form fluorine plasma. In one embodiment, the source gas g1 may include at least one of NF₃, SF₆, CF₄, CHF₃, CH₃F, CH₂F₂, C₂F₆, C₄F₈, HF, C₂F₄, C₃F₆ and C₄F₈. In an embodiment of the disclosure, the source gas g1 may include NF₃. The third power source 220 connected to the remote plasma source 200 may operate at a power of about 1000 W to about 30000 W. The remote plasma source 200 receiving the source gas g1 may form fluorine plasma including fluorine radicals.

Furthermore, the component 300 may be heated (operation S130). Heating the component 300 (operation S130) may be performed simultaneously with generating the fluorine plasma (operation S120). In one embodiment, the component 300 may be heated at a temperature of about 380° C. to about 500° C. The component 300 may be heated by a method such as conduction, convection, or radiation. In one embodiment, the component 300 may receive heat through the support 110 or may be heated by other means. By heating the component 300, magnesium (Mg) atoms included in the component 300 may move to a surface of the component 300 to generate and increase surface segregation of magnesium (Mg). In one embodiment, when the component 300 having a magnesium (Mg) content of about 1 wt % is heated, the magnesium (Mg) content on the surface of the component 300 may be increased to about 4 wt %. When a temperature of the component 300 is heated at a temperature of 380° C. or less, the surface segregation phenomenon may not be sufficient. In one embodiment, when exposed to the fluorine plasma, a (dense) protective layer 330 described below may not be formed, or a thickness of the protective layer 330 may not be sufficiently thick. When the temperature of the component 300 is heated at a temperature of 500° C. or higher, the physical properties of the component 300 may be weakened and a strength thereof may be reduced.

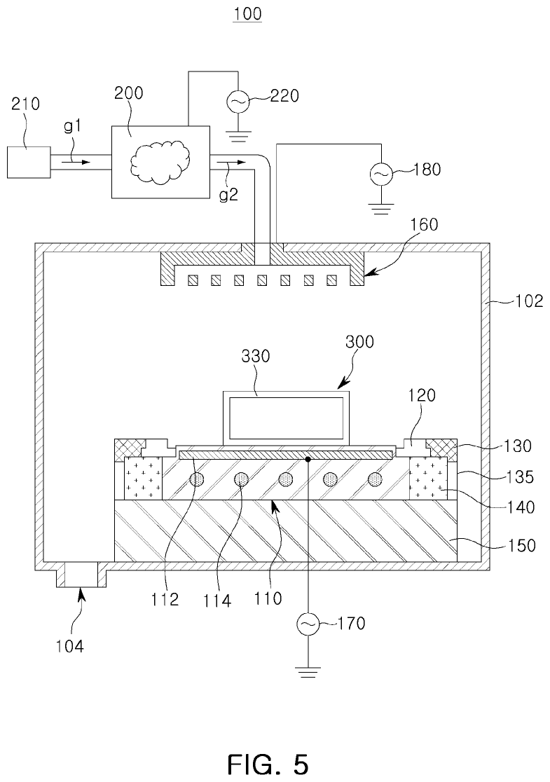

In FIGS. 1 and 5, the generated plasma may be provided in the process chamber 100 to form a protective layer 330 on the surface of the component 300 (operation S140). In one embodiment, the gas supply unit 210 may provide a carrier gas to the remote plasma source 200, and a gas g2 including the fluorine plasma and the carrier gas may be provided into the process chamber 100 through the shower head 160. The carrier gas may include an inert gas. In one embodiment, the carrier gas may include at least one of argon (Ar), helium (He), and nitrogen (N₂). The pressure of the fluorine plasma provided into the process chamber 100 may be about 0.5 Torr to about 10 Torr. Please note that ‘Torr’ is a unit of pressure defined to be exactly 1/760 of one standard atmosphere (101325 Pa). A flow rate of the fluorine plasma and the carrier gas may be about 1000 sccm to 15000 sccm. Please note that ‘sccm’ (standard cubic centimeters per minute) is a unit used to qualify the flow of a fluid. 1 sccm is identical to 1 cm³_{STP}/min. The time for the fluorine plasma to be provided into the process chamber 100 may be about 1 minute to about 1000 minutes.

Heating components (operation S130) may be performed before plasma is provided to the process chamber 100, and may continue to be performed in the operation of forming the protective layer 330 (operation S130). In one embodiment, while the fluorine plasma is provided into the process chamber 100, the component 300 may be heated at a temperature of about 380° C. to about 500° C.

The fluorine plasma provided into the process chamber 100 may react with magnesium (Mg) included in the component 300 to form the protective layer 330. In an embodiment of the disclosure, the protective layer 330 may include magnesium fluoride (MgF₂). The protective layer 330 may be formed on all or a portion of the surface of the component 300.

When the component 300 including aluminum (Al) is used, aluminum fluoride (AlF₃) may be formed by a cleaning gas including fluorine (F) during a cleaning process. Aluminum fluoride (AlF₃) may form a porous layer on the surface of the component 300. Fluoride radicals may penetrate into aluminum fluoride (AlF₃) to cause continuous fluoridation, aluminum fluoride (AlF₃) may be vaporized at high temperatures to cause aluminum particles in the process chamber 100, and the surface roughness of the component 300 may be increased. However, according to embodiments of the disclosure, the protective layer 330 including magnesium fluoride (MgF₂) may be formed on the surface of the component 300. Since the protective layer 330 is not a porous layer but a dense layer, the fluorine radicals may be prevented from penetrating into the component 300, and accordingly, aluminum (Al) below magnesium fluoride (MgF₂) may be suppressed from being fluorinated. Therefore, it is possible to reduce defects in a semiconductor device by reducing the particles in the process chamber 100. Furthermore, it is possible to reduce a time-dependent change in the process by maintaining a constant condition of the surface of the component. In one embodiment, during a deposition process such as chemical vapor deposition (CVD), atomic vapor deposition (ALD), and physical vapor deposition (PVD) during a semiconductor process, a change in emissivity caused by the formation of aluminum fluoride in the shower head 160 may be suppressed to constantly maintain the temperature of the substrate during the semiconductor manufacturing process, thereby maintaining a film deposition rate of a semiconductor device.

In an embodiment of the disclosure, a thickness of the protective layer 330 may be about 100 nm to about 300 nm. In an embodiment, a porosity of the protective layer 330 may be about 0.1% to about 1%. In an embodiment, the protective layer 330 does not include aluminum fluoride (AlF₃) and may be a single layer including magnesium fluoride (MgF₂).

In an embodiment of the disclosure, the protective layer 330 including magnesium fluoride (MgF₂) may also be formed on a surface of an aluminum-containing component among the components of the process chamber 100 by the method of surface treatment described above.

In an embodiment of the disclosure, a seasoning process may be performed in the process chamber 100 in which the process of forming the protective layer (operation S140) has been performed. In one embodiment, the process of forming the protective layer 330 (operation S140) may be performed in a state in which the component 300 is installed in the process chamber 100, and the process chamber 100 may be cleaned by the process of forming the protective layer 330 (operation S140), so that a separate seasoning process may not be required.

The seasoning process refers to forming a fluoride layer on a surface of an inner wall of the process chamber 100 by repeating a deposition process and a cleaning process using a cleaning gas such as NF₃ after replacing the component 300 of the process chamber 100 and before forming a circuit element. This is meant to maintain a constant state of the process chamber 100. As in the embodiments of the disclosure, the seasoning process may be omitted when the surface treatment is performed in a state in which the component 300 is installed in the process chamber 100.

In some embodiments of the disclosure, after forming the protective layer 330, the component 300 may be installed in a process chamber different from the process chamber 100 in which the process of forming the protective layer 330 (operation S130) was performed. In this case, since the protective layer 330 including magnesium fluoride (MgF₂) is formed on the surface of the component 300, the seasoning process may be omitted or the time for the sintering process may be reduced after installing the component 300.

In general, as the semiconductor device manufacturing process is repeated, components in the process chamber may be deteriorated. In one embodiment, gas including fluorine may be used during etching and dry cleaning processes, and components in the process chamber may react with fluorine radicals generated from the gas to be fluorinated. Accordingly, aluminum fluoride (AlF₃) may be formed on the surface of the component, and aluminum fluoride (AlF₃) may be vaporized at high temperatures, which may cause particles in the process chamber, and may cause defects in the semiconductor devices. Furthermore, when performing the deposition process using a fluorinated shower head, a change in emissivity due to a change in surface illumination may cause a temperature change of the substrate and may reduce a deposition rate of a thin film.

However, according to embodiments of the disclosure, a protective layer including magnesium fluoride (MgF₂) may be formed on a surface of a component including aluminum, and the protective layer may prevent aluminum included in the component from being fluorinated. Accordingly, even if the semiconductor manufacturing process and the cleaning process of process chamber are repeated, the condition in the chamber may be maintained constantly. Furthermore, it is possible to prevent a decrease in the deposition rate of the thin film, and to prevent and reduce the generation of particles in the process chamber. Therefore, the defects in the semiconductor devices manufactured in the process chamber may be prevented and reduced.

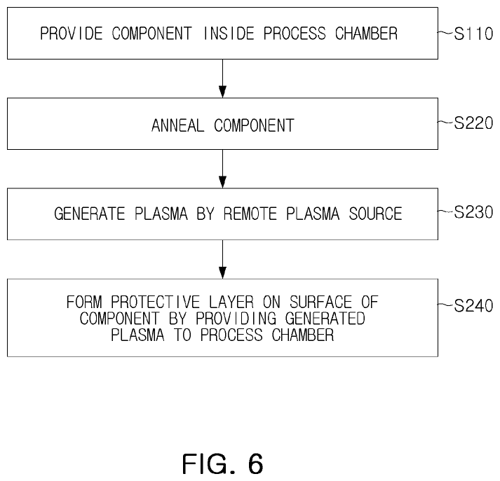

FIG. 6 is a flowchart illustrating a method of surface treatment according to an embodiment of the disclosure.

In FIG. 6, a method of surface treatment according to an embodiment of the disclosure may include providing a component 300 in a process chamber connected to a remote plasma source 200 (operation S110), annealing the component 300 (operation S220), generating plasma in the remote plasma source 200 (operation S230), and forming a protective layer 330 on a surface of the component 300 by providing the generated plasma to the process chamber (operation S240). Since operation S110, operation S230 and operation S240 may be identical or similar to those described with reference to FIG. 1, a detailed description thereof may be omitted.

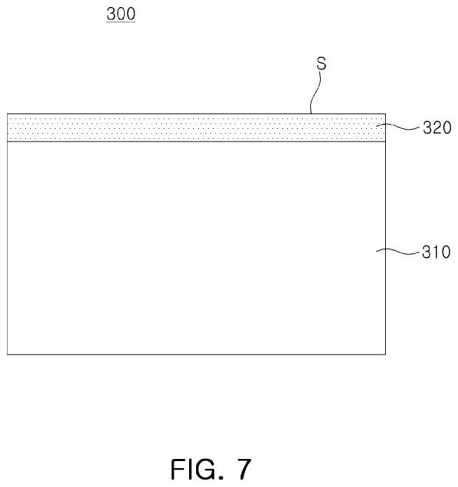

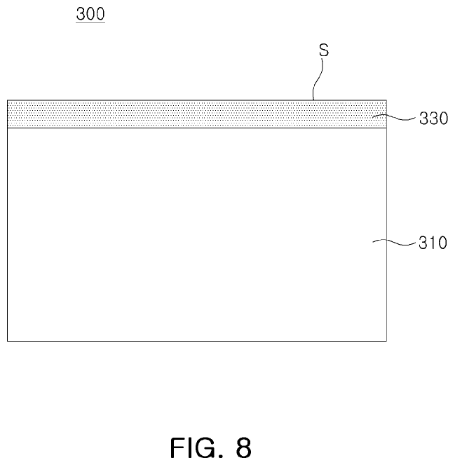

FIGS. 7 and 8 are views illustrating a method of surface treatment according to an embodiment of the disclosure.

In FIGS. 6 and 7, in an embodiment of the disclosure, after the component 300 is provided in the process chamber 100 (operation S110), the component 300 may be annealed (operation S220). In one embodiment, the component 300 may be annealed in a vacuum state in an internal space of the process chamber 100. In an embodiment of the disclosure, the component 300 may be heated at a temperature of about 380° C. to about 500° C. The pressure in the process chamber 100 may be about 5 mTorr to about 50 mTorr. An annealing time may be about 1 hour to about 5 hours.

As illustrated in FIG. 7, a component 300 may include a surface region 320 close to a surface S and a bulk layer 310 below the surface region 320. The bulk layer 310 may include aluminum (Al), magnesium (Mg), and other metal elements. As described above, when the component 300 is heated, surface segregation may occur. Accordingly, magnesium (Mg) included in the bulk layer 310 may move to the surface S to form a surface region 320 having a relatively higher magnesium (Mg) content than that of the bulk layer 310. In one embodiment, when the component 300 having the magnesium (Mg) content of 1 wt % or less is annealed, the magnesium (Mg) content on the surface S of the component 300 may be increased to 4 wt % or more.

In FIGS. 6 and 8, plasma may be provided to the process chamber 100 to form a protective layer 330 on the surface S of the component 300 (operation S240). The protective layer 330 may be formed in the surface region 320. As described above, the protective layer 330 may include magnesium fluoride (MgF₂), and may prevent the formation of aluminum fluoride (AlF₃).

In the method of surface treatment described with reference to FIG. 1, the surface region 320 and the protective layer 330 illustrated in FIGS. 7 and 8 may be formed on the surface of the component 300.

TABLE 1

| | | AlF₃ | MgF₂ |
|---|---|---|---|
| | Mg content | formation | thickness (t) |
| Comparative | Mg < 0.5 wt % | ◯ | t = 44~54 nm |
| Example 1 | | | |
| Comparative | 0.5 wt % < Mg < 2.0 | ◯ | — |
| Example 2 | wt % | | |
| Example 1 of | 0.5 wt % < Mg < 2.0 | X | t = 100~150 nm |
| the disclosure | wt % | | |
| Example 2 of | 2.0 wt % < Mg < 5.5 | X | t = 240~330 nm |
| the disclosure | wt % | | |
| Comparative | Mg > 5.5 wt % | — | — |
| Example 3 | | | |

Table 1 illustrates the results of forming the protective layer according to examples of the disclosure and comparative examples of the disclosure. The components used in the examples of the disclosure and comparative examples of Table 1 are metals including aluminum (Al) and magnesium (Mg).

In Table 1, for Comparative Example 1, the content of magnesium (Mg) is 0.5 wt % or less. As a result of surface treatment of the component of Comparative Example 1, a protective layer including magnesium fluoride (MgF₂) was formed, but a thickness of magnesium fluoride (MgF₂) was 44 nm to 54 nm, and penetration of fluorine radicals could not be prevented. That is, aluminum (Al) below magnesium fluoride (MgF₂) reacted with fluorine radicals to form aluminum fluoride (AlF₃).

For Comparative Example 2 and Example 1 of the disclosure, the content of magnesium (Mg) is 0.5 wt % or more and 2.0 wt % or less. Before the surface treatment process, an annealing process was not performed on the component of Comparative Example 2, but the annealing process was performed on the component of Example 1 of the disclosure.

Both magnesium fluoride (MgF₂) and aluminum fluoride (AlF₃) were formed in the components of Comparative Example 2. Magnesium fluoride (MgF₂) and aluminum fluoride (AlF₃) were present in a mixed state to form a porous layer. However, magnesium fluoride (MgF₂) was formed on the surface of the component of Example 1 of the disclosure to have a thickness of 100 nm to 150 nm, and aluminum fluoride (AlF₃) was not formed.

In the case of Example 2 of the disclosure, the content of magnesium (Mg) is 2.0 wt % or more and 5.5 wt % or less. As a result of surface treatment of the component of Example 2 of the disclosure, magnesium fluoride (MgF₂) was formed to have a thickness between 240 nm and 330 nm, and aluminum fluoride (AlF₃) was not formed.

In the case of Comparative Example 3, the content of magnesium (Mg) is 5.5 wt % or more. As a result of surface treatment of the component of Comparative Example 3, magnesium fluoride (MgF₂) was formed, and aluminum fluoride (AlF₃) was not formed. However, when the component includes 5.5 wt % or more of magnesium (Mg), it may be vulnerable to corrosion and cracking at high temperatures.

Accordingly, the content of magnesium (Mg) of the component according to the embodiments of the disclosure may be about 0.5 wt % to about 5.5 wt %. Here, the content of magnesium (Mg) of the component may denote the content of the magnesium (Mg) of the bulk layer 310.

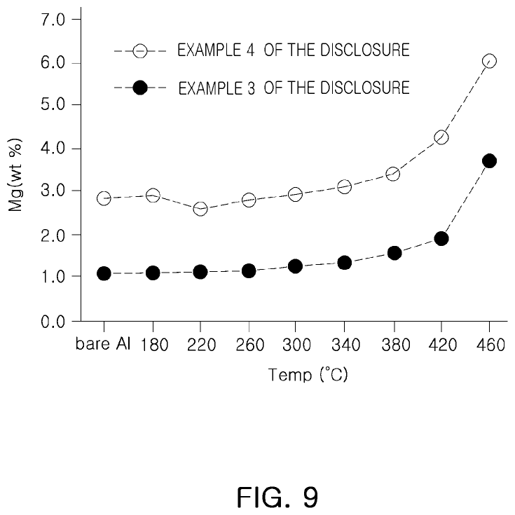

FIG. 9 is a view illustrating an annealing method according to an embodiment of the disclosure. FIG. 9 illustrates a magnesium (Mg) content of a surface of a component according to the heating temperature.

In FIG. 9, according to Example 3 of the disclosure, the content of magnesium (Mg) of the surface of the component before annealing (corresponding to bare Al in FIG. 9) may be about 1 wt %. As illustrated in FIG. 9, the content of magnesium (Mg) of the surface of the component increases as the temperature increases, and when the temperature of the component is about 460° C., the content of magnesium (Mg) may be about 3 wt %.

According to Example 4 of the disclosure, the content of magnesium (Mg) of a surface of a component before annealing may be about 3 wt %. The content of magnesium (Mg) of the surface of the component increases as the temperature increases, and when the temperature of the component is about 460° C., the content of magnesium (Mg) may be about 6 wt %.

Accordingly, in order to increase a formation speed and a thickness of the protective layer, the component may be heated at a temperature of about 380° C. or more. Furthermore, as described above, a component heating temperature may be about 500° C. or less to prevent an intensity of the component from decreasing.

TABLE 2

| | | Surface | |
|---|---|---|---|
| | | Illumination | MgF₂ |
| | | (Ra) | Thickness (t) |
| Comparative | After direct plasma | 0.33 | 1.7 μm~2.5 μm |
| Example 4 | treatment | | |
| | After a high- | 0.33 | 0.9 μm~1.0 μm- |
| | temperature NF₃ | | |
| | cleaning process | | |
| Example 5 of | After remote plasma | 0.08 | 165 nm |
| the disclosure | treatment | | |
| | After a high- | 0.09 | 213 nm |
| | temperature NF₃ | | |
| | cleaning process | | |
| Comparative | After ion implantation | 0.37 | 75 nm |
| Example 5 | After a high- | 0.44 | 150 nm-230 nm |
| | temperature NF₃ | | |
| | cleaning process | | |

Table 2 shows results of magnesium fluoride (MgF₂) and fluorine radical penetration through a comparison of protective layer formation and a high-temperature cleaning process (repeated 200 times) according to Example of the disclosure and Comparative Examples. The surface roughness before the surface treatment was evaluated in a specimen controlled to 0.1 μm. The components used in Example of the disclosure and Comparative Examples of Table 2 are metals including aluminum (Al) and magnesium (Mg).

In Table 2, in Comparative Example 4, after the direct plasma was formed in the process chamber, a porous layer in which magnesium fluoride (MgF₂) and aluminum fluoride (AlF₃) were mixed was formed on a surface of a component. After the surface treatment, the surface roughness increased to 0.33. A change in the surface roughness of the component may affect a semiconductor manufacturing process. Due to the cleaning process, magnesium fluoride (MgF₂) and aluminum fluoride (AlF₃) caused a time-dependent change in a mixed fluoride layer. Aluminum fluoride (AlF₃) was partially etched and magnesium fluoride (MgF₂) was grown, but magnesium fluoride (MgF₂) did not form a dense single layer.

In the case of Example 5 of the disclosure, magnesium fluoride (MgF₂) formed a dense single layer having a thickness of 165 nm on a surface of a component using fluorine plasma including fluorine radicals formed by remote plasma. After a cleaning process, a thickness of magnesium fluoride (MgF₂) was maintained to be 213 nm, similar to that before the surface treatment. In the case of Example 5 of the disclosure, the surface roughness of the component hardly changed before and after the formation of the protective layer and before and after the cleaning process. Since there is no change in surface roughness and ingredients after the cleaning process, a condition of a semiconductor device process chamber may be maintained constantly without degradation of the component.

In the case of Comparative Example 5, fluorine ions were implanted into a surface of a component by an ion implantation process in a process chamber. Magnesium fluoride (MgF₂) formed a dense single layer having a thickness of 75 nm on the surface of the component. After the surface treatment, the surface roughness increased to 0.37. After the cleaning process, a thickness of magnesium fluoride (MgF₂) increased to 150 nm to 230 nm, and the surface roughness increased to 0.44. As described above, the change in surface roughness of the component may affect the semiconductor manufacturing process.

Comparing the results of Comparative Examples 4 and 5, it may be seen that the component according to Example 5 of the disclosure using the remote plasma source 200 have little change in surface roughness, and magnesium fluoride (MgF₂) is densely and thickly formed.

The disclosure is not limited to the above-described embodiments and the accompanying drawings but is defined by the appended claims. Therefore, those of ordinary skill in the art may make various replacements, modifications, or changes without departing from the scope of the disclosure defined by the appended claims, and these replacements, modifications, or changes should be construed as being included in the scope of the disclosure.

What is claimed is:

1. A method of surface treatment, comprising:
providing a component in a first process chamber;
generating fluorine plasma with a remote plasma source connected to the first process chamber; and
forming a protective layer on a surface of the component by providing the fluorine plasma to the first process chamber,
wherein the protective layer comprises magnesium fluoride,
wherein a magnesium content of the component is about 0.5 wt % to about 5.5 wt %, and
wherein a thickness of the protective layer is about 100 nm to about 300 nm.

2. The method of surface treatment of claim 1, wherein the forming of the protective layer comprises heating the component at a temperature of about 380° C. to about 500° C.

3. The method of surface treatment of claim 1, wherein the forming of the protective layer comprises maintaining a pressure of the first process chamber as about 0.5 Torr to about 10 Torr.

4. The method of surface treatment of claim 1, wherein, before the providing of the fluorine plasma to the first process chamber, further comprising heating the component by an annealing process.

5. The method of surface treatment of claim 4, further comprising increasing the magnesium content of the surface of the component by the annealing process.

6. The method of surface treatment of claim 4, further comprising performing the annealing process about 1 hour to about 5 hours.

7. The method of surface treatment of claim 4, further comprising performing the annealing process at a pressure of about 5 mTorr to about 50 mTorr.

8. The method of surface treatment of claim 1, wherein the component comprises a bulk layer comprising aluminum and magnesium, and
wherein the protective layer is disposed on the bulk layer.

9. The method of surface treatment of claim 8, wherein the protective layer does not include aluminum fluoride.

10. The method of surface treatment of claim 1, further comprising providing a source gas to the remote plasma source,
wherein the fluorine plasma is generated from the source gas.

11. The method of surface treatment of claim 10, wherein the source gas comprises at least one of NF₃, SF₆, CF₄, CHF₃, CH₃F, CH₂F₂, C₂F₆, C₄F₈, HF, C₂F₄, C₃F₆ and C₄F₅.

12. The method of surface treatment of claim 1, further comprising installing the component on which the protective layer is formed, in a second process chamber.

13. The method of surface treatment of claim 1, wherein a porosity of the protective layer is about 0.1% to about 1%.

14. The method of surface treatment of claim 1, further comprising operating a power source connected to the remote plasma source at a power of about 1000 W to about 30000 W.

15. The method of surface treatment of claim 1, wherein the first process chamber comprises a support comprising a heater, and
wherein the component is disposed on the support.

16. A method of surface treatment, comprising:
installing a component in a process chamber;
generating fluorine plasma with a remote plasma source connected to the process chamber; and
forming a protective layer on a surface of the component by providing the fluorine plasma to the process chamber,
wherein the protective layer comprises magnesium fluoride,
wherein a magnesium content of the component is about 0.5 wt % to about 5.5 wt %, and
wherein a thickness of the protective layer is about 100 nm to about 300 nm.

17. The method of surface treatment of claim 16, wherein the installing of the component in the process chamber comprises installing the component in the process chamber that comprises a housing; a support on a lower portion of the housing; a ring structure surrounding a side surface of the support, and an isolator provided below the support; a shower head on an upper portion of the housing and facing the support; and an outlet on a sidewall of the housing,
wherein the component comprises at least one of a first internal wall of the housing, a second internal wall of the outlet, the ring structure, the isolator, and the shower head.

18. The method of surface treatment of claim 16, wherein the protective layer is a single layer comprising the magnesium fluoride that does not include aluminum fluoride.

19. A method of surface treatment, comprising:
providing a component comprising a bulk layer including aluminum and magnesium in a process chamber;
annealing the component to form, on the bulk layer, a surface region comprising a higher magnesium content than that of the bulk layer;
generating fluorine plasma with a remote plasma source connected to the process chamber; and
forming a protective layer on the surface region by providing the fluorine plasma to the process chamber,
wherein the protective layer comprises magnesium fluoride,
wherein a magnesium content of the component is about 0.5 wt % to about 5.5 wt %, and
wherein a thickness of the protective layer is about 100 nm to about 300 nm.

20. The method of surface treatment of claim 19, wherein the protective layer is disposed on the bulk layer and does not include aluminum fluoride.
